(19) United States
(12) Patent Application Publication
(10) Pub. No.: US 2023/0380145 A1
(43) Pub. Date: Nov. 23, 2023

(54) SELF-ALIGNED VERTICAL BITLINE FOR THREE-DIMENSIONAL (3D) DYNAMIC RANDOM-ACCESS MEMORY (DRAM) DEVICES

(71) Applicant: Applied Materials, Inc., Santa Clara, CA (US)

(72) Inventors: Zhijun CHEN, San Jose, CA (US); Fredrick FISHBURN, Aptos, CA (US); Ying-Bing JIANG, Woodland, CA (US); Avgerinos V. GELATOS, Scotts Valley, CA (US)

(21) Appl. No.: 18/141,557

(22) Filed: May 1, 2023

Related U.S. Application Data
(60) Provisional application No. 63/343,476, filed on May 18, 2022.

(51) Int. Cl. H10B 12/00; H10B 80/00; H01L 25/065

(52) U.S. Cl. CPC H10B 12/482; H10B 80/00; H01L 25/0657; H10B 12/488; H10B 12/02

(57) ABSTRACT

A semiconductor structure includes a plurality of memory levels stacked in a first direction, each of the plurality of memory levels including a semiconductor layer, a word line metal layer, and an interface on a cross section of the semiconductor layer, a spacer between adjacent memory levels of the plurality of memory levels in the first direction, and a bit line in contact with the interface of each of the plurality of memory levels, the bit line extending in the first direction. The bit line comprises metal material, and the interface comprises silicide.

### CROSS-REFERENCE TO RELATED APPLICATIONS

This application claims priority to U.S. Provisional Application Ser. No. 63/343,476 filed May 18, 2022, which is herein incorporated by reference in its entirety.

### BACKGROUND

### Field

Embodiments described herein generally relate to semiconductor device fabrication, and more particularly, to systems and methods of forming vertical bit lines in three-dimensional dynamic random-access memory devices.

### Description of the Related Art

Three-dimensional (3D) dynamic random-access memory (DRAM) devices pose challenges in manufacturability due to their three-dimensional (3D) designs and small sizes. Individual memory cells, each of which includes a field-effect transistor (FET) device, need to be connected to a bit line at the source/drain regions of the FET device. Fabrication of such bit lines typically requires line-of-sight processing and multiple process steps including a high-aspect-ratio (HAR) etching process to form slots for bit lines. For example, a 3D DRAM device may include alternating layers of silicon (Si) and silicon germanium (SiGe), in which silicon germanium (SiGe) layers are selectively recessed. Vertical bit lines may be formed by filling HAR slots through the silicon (Si) layers with polycrystalline silicon (poly-Si). This conventional approach for forming vertical bit lines in a 3D DRAM device results in voids in the resultant vertical bit lines, leading to relatively high parasitic resistance.

Thus, there is a need for systems and methods that can fabricate vertical bit lines in a 3D DRAM device with minimized parasitic resistance by reduced processing steps.

### SUMMARY

Embodiments of the present disclosure provide a semiconductor structure. The semiconductor structure includes a plurality of memory levels stacked in a first direction, each of the plurality of memory levels including a semiconductor layer, a word line metal layer, and an interface on a cross section of the semiconductor layer, a spacer between adjacent memory levels of the plurality of memory levels in the first direction, and a bit line in contact with the interface of each of the plurality of memory levels, the bit line extending in the first direction. The bit line comprises metal material, and the interface comprises silicide.

Embodiments of the present disclosure also provide a method of forming a metal bit line in a semiconductor device. The method includes performing a first selective deposition process to form a metal silicide layer selectively on a sidewall of a trench, the sidewall of the trench comprising a first cross section of each of a plurality of semiconductor layers stacked in a first direction, and a second cross section of a spacer disposed between adjacent semiconductor layers of the plurality of semiconductor layers, performing a second selective deposition process to form a metal layer selectively on the sidewall of the trench, and performing a filling process, the filling process comprising depositing dielectric material within the trench. The metal layer on the sidewall of the trench is continuous over the plurality of semiconductor layers, forming a metal bit line.

Embodiments of the present disclosure further provide a three-dimensional (3D) dynamic random-access memory (DRAM) device. The 3D DRAM device includes a plurality of memory levels stacked in a first direction, each of the plurality of memory levels including a semiconductor layer having a first end and a second end in a second direction that is orthogonal to the first direction, a word line metal layer, and an interface on a cross section at the first end of the semiconductor layer, a spacer between adjacent memory levels of the plurality of memory levels in the first direction, and a bit line in contact with the interface of each of the plurality of memory levels, the bit line extending in the first direction. The bit line comprises metal material, and the interface comprises silicide.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic top-view diagram of an example multi-chamber processing system according to one embodiment.

FIG. 2A is a schematic diagram of a portion of a three-dimensional (3D) memory cell array of dynamic random access memory (DRAM) cells according to one embodiment. FIG. 2B is a schematic diagram of a DRAM cell.

FIG. 3A is an isometric view of a semiconductor structure according to one embodiment. FIGS. 3B, 3C, 3D, and 3E are cross-sectional views of the semiconductor structure shown in FIG. 3A.

FIG. 4 depicts a process flow diagram of a method of forming a contact trench structure in a semiconductor structure according to one embodiment.

FIGS. 5A, 5B, 5C, 5D, and 5E are cross-sectional views of a portion of a semiconductor structure according to one embodiment.

To facilitate understanding, identical reference numerals have been used, where possible, to designate identical elements that are common to the figures. It is contemplated that elements and features of one embodiment may be beneficially incorporated in other embodiments without further recitation. In the figures and the following description, an orthogonal coordinate system including an X-axis, a Y-axis, and a Z-axis is used. The directions represented by the arrows in the drawing are assumed to be positive directions for convenience.

### DETAILED DESCRIPTION

The embodiments described herein provide systems and methods for forming transistor devices for extremely scaled process nodes, such as 3D DRAM devices with vertical metal bit lines and interfaces between the vertical bit lines and a FET device that forms a memory cell. The vertical bit lines are formed of metal, such as molybdenum (Mo), reducing resistance of the bit lines, as compared to a polycrystalline silicon bit line. The interfaces are formed of metal silicide, such as molybdenum silicide (MoSi₂, MoSi, Mo₂Si), by a selective self-aligning deposition process and provide an ohmic contact between the FET device and the vertical bit lines, reducing contact parasitic resistance.

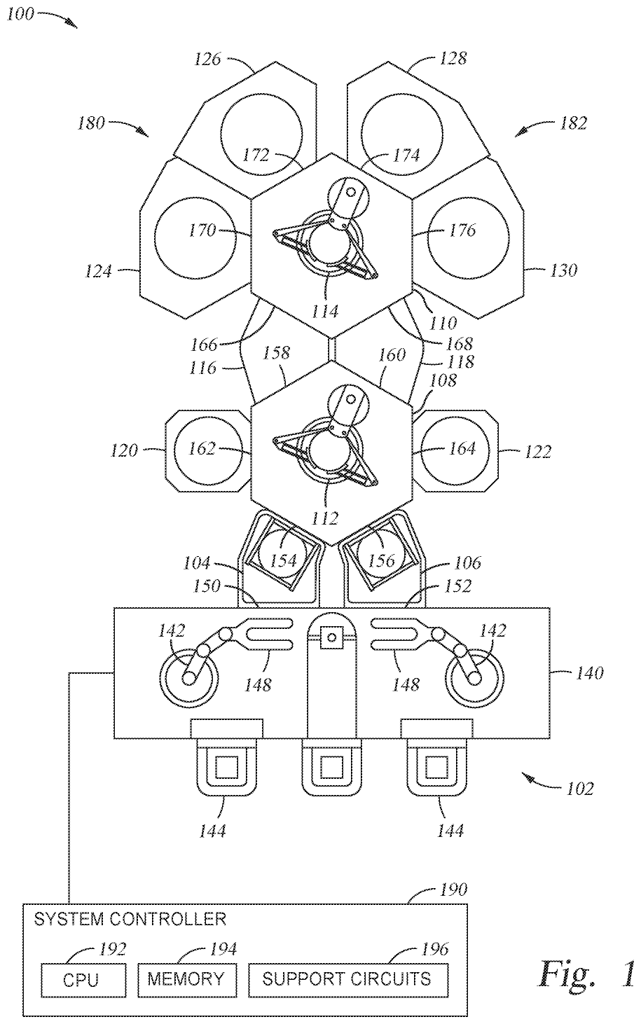

FIG. 1 is a schematic top-view diagram of an example of a multi-chamber processing system 100 according to some examples of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, wafers in the processing system 100 can be processed in and transferred between the various chambers without exposing the wafers to an ambient environment exterior to the processing system 100 (e.g., an atmospheric ambient environment such as may be present in a fab). For example, the wafers can be processed in and transferred between the various chambers in a low pressure (e.g., less than or equal to about 300 Torr) or vacuum environment without breaking the low pressure or vacuum environment between various processes performed on the wafers in the processing system 100. Accordingly, the processing system 100 may provide for an integrated solution for some processing of wafers.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 140 and factory interface robots 142 to facilitate transfer of wafers. The docking station 140 is configured to accept one or more front opening unified pods (FOUPs) 144. In some examples, each factory interface robot 142 generally comprises a blade 148 disposed on one end of the respective factory interface robot 142 configured to transfer the wafers from the factory interface 102 to the load lock chambers 104, 106.

The load lock chambers 104, 106 have respective ports 150, 152 coupled to the factory interface 102 and respective ports 154, 156 coupled to the transfer chamber 108. The transfer chamber 108 further has respective ports 158, 160 coupled to the holding chambers 116, 118 and respective ports 162, 164 coupled to processing chambers 120, 122. Similarly, the transfer chamber 110 has respective ports 166, 168 coupled to the holding chambers 116, 118 and respective ports 170, 172, 174, 176 coupled to processing chambers 124, 126, 128, 130. The ports 154, 156, 158, 160, 162, 164, 166, 168, 170, 172, 174, 176 can be, for example, slit valve openings with slit valves for passing wafers therethrough by the transfer robots 112, 114 and for providing a seal between respective chambers to prevent a gas from passing between the respective chambers. Generally, any port is open for transferring a wafer therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 142 transfers a wafer from a FOUP 144 through a port 150 or 152 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the wafer between, for example, the atmospheric environment of the factory interface 102 and the low pressure or vacuum environment of the transfer chamber 108.

With the wafer in the load lock chamber 104 or 106 that has been pumped down, the transfer robot 112 transfers the wafer from the load lock chamber 104 or 106 into the transfer chamber 108 through the port 154 or 156. The transfer robot 112 is then capable of transferring the wafer to and/or between any of the processing chambers 120, 122 through the respective ports 162, 164 for processing and the holding chambers 116, 118 through the respective ports 158, 160 for holding to await further transfer. Similarly, the transfer robot 114 is capable of accessing the wafer in the holding chamber 116 or 118 through the port 166 or 168 and is capable of transferring the wafer to and/or between any of the processing chambers 124, 126, 128, 130 through the respective ports 170, 172, 174, 176 for processing and the holding chambers 116, 118 through the respective ports 166, 168 for holding to await further transfer. The transfer and holding of the wafer within and among the various chambers can be in the low pressure or vacuum environment provided by the gas and pressure control system.

The processing chambers 120, 122, 124, 126, 128, 130 can be any appropriate chamber for processing a wafer. In some examples, the processing chamber 122 can be capable of performing a cleaning process, the processing chamber 120 can be capable of performing an etch process, and the processing chambers 124, 126, 128, 130 can be capable of performing respective epitaxial growth processes. The processing chamber 122 may be a SiCoNi™ Preclean chamber available from Applied Materials of Santa Clara, Calif. The processing chamber 120 may be a Selectra™ Etch chamber available from Applied Materials of Santa Clara, Calif.

A system controller 190 is coupled to the processing system 100 for controlling the processing system 100 or components thereof. For example, the system controller 190 may control the operation of the processing system 100 using a direct control of the chambers 104, 106, 108, 116, 118, 110, 120, 122, 124, 126, 128, 130 of the processing system 100 or by controlling controllers associated with the chambers 104, 106, 108, 116, 118, 110, 120, 122, 124, 126, 128, 130. In operation, the system controller 190 enables data collection and feedback from the respective chambers to coordinate performance of the processing system 100.

The system controller 190 generally includes a central processing unit (CPU) 192, memory 194, and support circuits 196. The CPU 192 may be one of any form of a general purpose processor that can be used in an industrial setting. The memory 194, or non-transitory computer-readable medium, is accessible by the CPU 192 and may be one or more of memory such as random access memory (RAM), read only memory (ROM), floppy disk, hard disk, or any other form of digital storage, local or remote. The support circuits 196 are coupled to the CPU 192 and may comprise cache, clock circuits, input/output subsystems, power supplies, and the like. The various methods disclosed herein may generally be implemented under the control of the CPU 192 by the CPU 192 executing computer instruction code stored in the memory 194 (or in memory of a particular process chamber) as, for example, a software routine. When the computer instruction code is executed by the CPU 192, the CPU 192 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

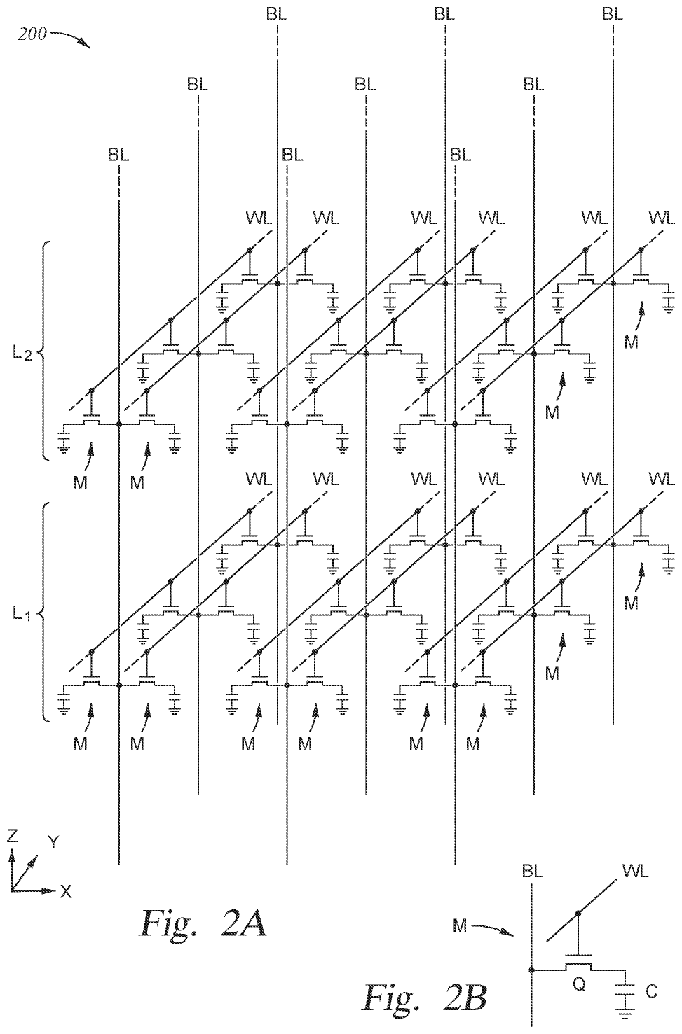

FIG. 2A is a schematic diagram of a portion of a three-dimensional (3D) memory cell array 200 of dynamic random access memory (DRAM) cells (also referred to as “memory cells”) M, according to one or more embodiments of the present disclosure.

As shown in FIG. 2B, a single memory cell M includes an access transistor Q and a storage capacitor C. A memory cell M stores a datum bit by storing a packet of charge (i.e., a binary one) or no charge (i.e., a binary zero) on the storage capacitor C. A datum bit is input and output by a bit line BL that is connected to the source/drain of the access transistor Q, and input is controlled by a word line WL that is connected to the gate of the access transistor Q.

The memory cell array 200 includes memory levels Lₙ (n=1, 2, 3, . . . ) (a first memory level L₁ and a second memory level L₂ are shown) stacked in the Z direction. Each memory level Lₙ includes two-dimensional (2-D) array of memory cells M. Although only two memory levels are shown in FIG. 2A, the memory cell array 200 may include more memory levels Lₙ (n=3, 4, . . . ) stacked above the second memory level L₂ in the Z direction.

In the memory cell array 200, bit lines BL extend vertically in the Z direction, and word lines WL extend horizontally in the Y-direction. Each of the bit lines BL is linked to the sources/drains of access transistors Q that are vertically aligned in the Z direction. Each of the word lines WL is linked to the gates of the access transistors Q that are horizontally aligned in the Y direction.

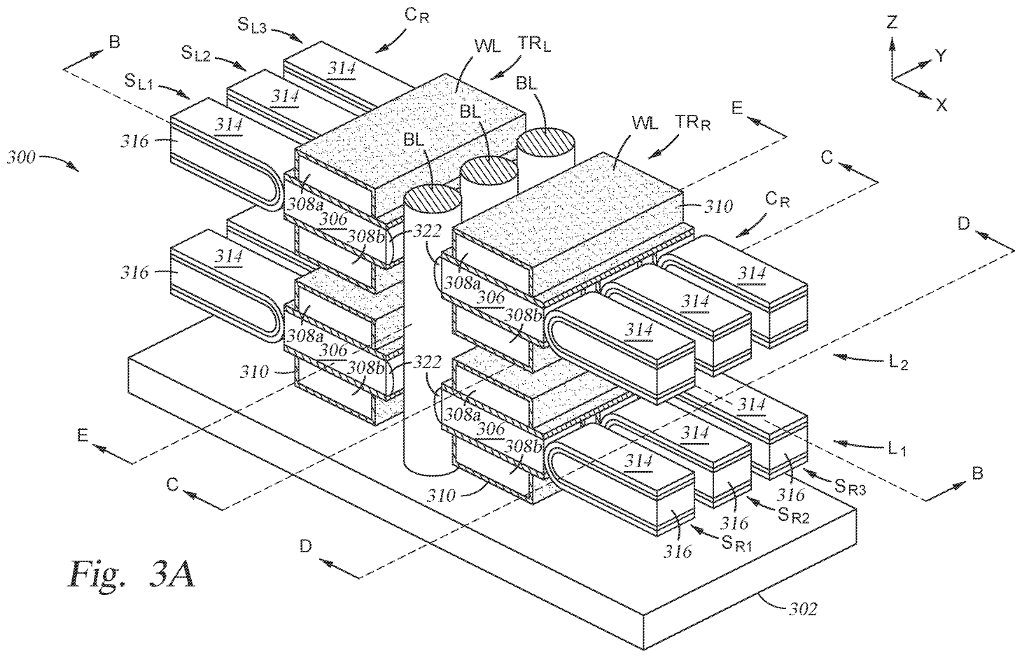

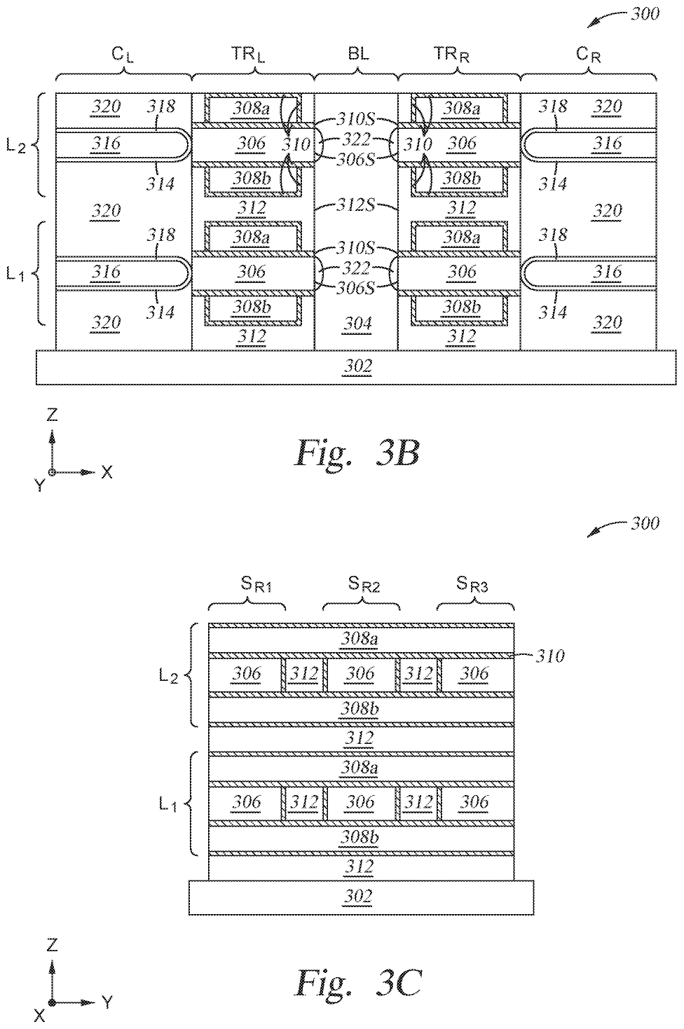

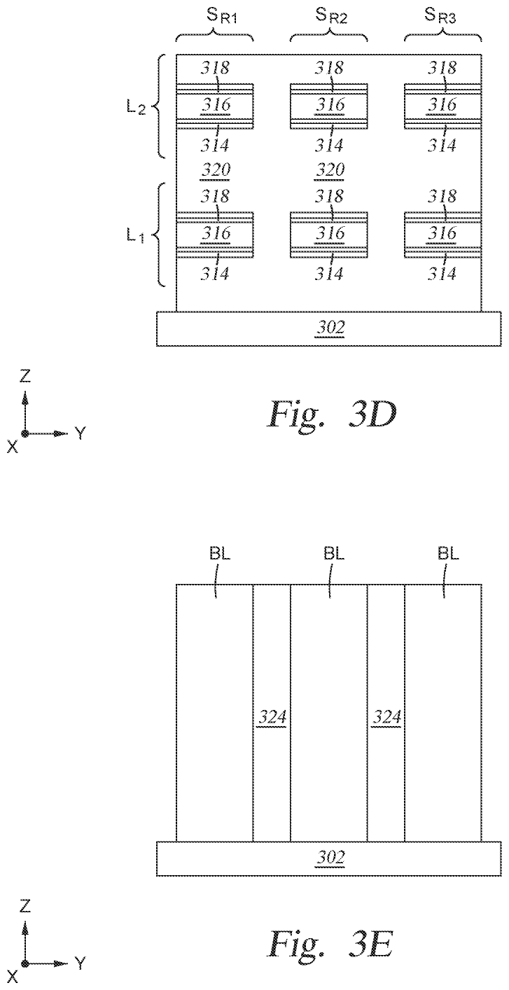

FIG. 3A is an isometric view of a portion of a semiconductor structure 300 that may form a 3D memory cell array, such as a portion of the memory cell array 200, according to one or more embodiments of the present disclosure. FIG. 3B is a cross-sectional view of a portion of the semiconductor structure 300 along the line B-B′ shown in FIG. 3A. FIG. 3C is a cross-sectional view of a portion of the semiconductor structure 300 along the line C-C′ shown in FIG. 3A. FIG. 3D is a cross-sectional view of a portion of the semiconductor structure 300 along the line D-D′ shown in FIG. 3A. FIG. 3E is a cross-sectional view of a portion of the semiconductor structure 300 along the line E-E′ shown in FIG. 3A. As shown, two memory levels L₁ and L₂ are stacked in the Z direction on a substrate 302. The semiconductor structure 300 may include more memory levels Lₙ (n=3, 4, . . . ) (not shown) stacked above the second memory level L₂ in the Z direction.

The semiconductor structure 300 includes a left field effect transistor (FET) module TR_{L}, a right FET module TR_{R} separated from the left FET module TR_{L} in the X direction by a trench 304. The semiconductor structure 300 further includes a left capacitor module CL adjacent to the left FET module TR_{L} in the X direction, and a right capacitor module CR adjacent to the right FET module TR_{R} in the X direction. The left FET module TR_{L} and the left capacitor module CL are divided into multiple sections S_{Lm}=1, 2, 3, . . . ) in the Y direction (S_{L1}, S_{L2}, and S_{L3} are shown in FIG. 3A). The right FET module TR_{R} and the right capacitor module CR are divided into multiple sections S_{Rm}=1, 2, 3, . . . ) in the Y direction (S_{R1}, S_{R2}, and S_{R3} are shown in FIGS. 3A, 3C, and 3D). The left FET module TR_{L} and the left capacitor module CL in each memory level Lₙ (n=1, 2, . . . ) in each section S_{Lm}=1, 2, 3) forming an access FET transistor Q and a storage capacitor C, respectively, together form a memory cell M. Similarly, the right FET module TR_{R} and the right capacitor module CR in each memory level Lₙ (n=1, 2, . . . ) in each section S_{Rm}=1, 2, 3) forming an access FET transistor Q and a storage capacitor C, respectively, together form a memory cell M. Although only three sections S_{Lm}=1, 2, 3) and S_{Rm}=1, 2, 3) are shown, more sections may be disposed along the Y direction.

The term “substrate” as used herein refers to a layer of material that serves as a basis for subsequent processing operations and includes a surface to be cleaned. The substrate 302 may be a silicon based material or any suitable insulating materials or conductive materials as needed. The substrate 302 may include a material such as crystalline silicon (e.g., Si<100> or Si<111>), silicon oxide, strained silicon, silicon germanium, doped or undoped polycrystalline silicon, doped or undoped silicon wafers and patterned or non-patterned wafers, silicon on insulator (SOI), carbon doped silicon oxides, silicon nitride, doped silicon, germanium, gallium arsenide, glass, or sapphire.

The FET modules TR_{L} and TR_{R} in the memory level Lₙ (n=1, 2, . . . ) each includes a semiconductor layer 306, and a word line metal layer 308a. In some embodiments, the FET modules TR_{L} and TR_{R} in the memory level Lₙ (n=1, 2, . . . ) each further includes a word line metal layer 308b. Cross sections 306S of the semiconductor layer 306 each act as a source/drain of the corresponding access transistor Q. The word line metal layer 308a and the word line metal layer 308b in the memory level Lₙ (n=1, 2, . . . ) extend in the Y direction and may be electrically connected to each other within the memory level Lₙ (the connection point not shown). The semiconductor layer 306 has gate oxides 310 above and below in the Z direction in the dual gate configuration. Each of the word line metal lays 308a and 308b has gate oxides 310 around the word line metal layers 308a, 308b and buried in a spacer 312. The FET modules TR_{L} and TR_{R} in the memory level Lₙ (n=1, 2, . . . ) are separated from the FET modules TR_{L} and TR_{R} in adjacent memory level Lₙ₊₁ by the spacer 312. The spacer 312 is also disposed to separate the semiconductor layer 306 between adjacent sections (e.g., S_{R1}, S_{R2}, and S_{R3} as shown in FIG. 3C) within the memory level Lₙ (n=1, 2, . . . ). The FET modules TR_{L} and TR_{R} in the memory level L₁ may be separated from the substrate 302 by the spacer 312. The semiconductor layers 306 may each have width in the Y direction of between about 20 nm and about 60 nm, for example, about 40 nm, and thickness in the Z direction of between about 10 nm and about 30 nm, for example, about 20 nm. A horizontal spacing between the adjacent semiconductor layers 306 in the Y direction may be between about 140 nm and about 180 nm, for example, about 160 nm, and a vertical spacing between the adjacent semiconductor layers 306 in the Z direction may be between about 50 nm and about 100 nm, for example, about 80 nm. The bit lines BL may have width in the Y direction of between about 40 nm and about 120 nm, for example, about 80 nm, and thickness in the X direction of between about 40 nm and about 120 nm, for example, about 80 nm. In some memory array designs, the BL is common to the left FET module TR_{L} and the right FET module TR_{R}, across the trench 304, and thus the width of the bit line BL in the X direction is the width of the trench 304. In these design, the word lines WL on the left FET module TR_{L} and on the right FET module TR_{R} may address two logical word line addresses and separately controlled. In some other memory array designs, two separate bit lines BL, one on the left FET module TR_{L} and the other on the right FET module TR_{R}, are formed. These bit lines BL are isolated from each other and can be separately connected to different global bit lines. Allowing a single word line connection to be used for the left word line WL and the right word line WL, greatly reducing the number and thus the area required for a deep word line “staircase” contacts.

The semiconductor layer 306 may be formed of silicon (Si) or silicon germanium (SiGe). The word line metal layers 308a, 308b may be formed from copper (Cu), cobalt (Co), tungsten (W), titanium (Ti), molybdenum (Mo), nickel (Ni), ruthenium (Ru), silver (Ag), gold (Au), iridium (Ir), tantalum (Ta), or platinum (Pt), or conductive oxides or nitrides thereof, or any combination thereof. The gate oxides 310 may be formed of silicon oxide (SiO₂), silicon oxynitride (SiON), a high-K dielectric material, such as hafnium oxide (HfO₂), zirconium oxide (ZrO₂), vanadium oxide (VO₂), titanium oxide (TiO₂), aluminum oxide (Al₂O₃), hafnium silicon oxide (HfSiO), zirconium silicon oxide (ZrSiO), niobium oxide (Nb₂O₅), tantalum pentoxide (Ta₂O₅), or any combination thereof. The spacer 312 may be formed of dielectric material, such as silicon dioxide (SiO₂), silicon nitride (Si₃N₄), silicon oxynitride (SiON), silicon oxycarbide (SiOCN), boron-doped silicon oxycarbonitride (SiOCBN), or any combination thereof.

The left capacitor module CL and the right capacitor module CR in the memory level Lₙ (n=1, 2, . . . ) each includes a first plate metal layer 314 that is electrically connected to the semiconductor layer 306 within the memory level Lₙ, a second plate metal layer 316 that is grounded (not shown), and a dielectric layer 318 between the first plate metal layer 314 and the second plate metal layer 316. The first plate metal layers 314 is surrounded by a dielectric layer 320. The dielectric layer 320 is also disposed to separate the first plate metal layers 314, the second plate metal layers 316, and the dielectric layers 320 between adjacent sections (e.g., S_{R1}, S_{R2}, and S_{R3} as shown in FIG. 3D). Between the first plate metal layer 314 and the semiconductor layer 306, a diffusion barrier layer (not shown) may be interposed. The first plate metal layer 314 and the second plate metal layer 316 may serve as two plates of a capacitor C. The first plate metal layer 314 and the second plate metal layers 316 may be formed of cobalt (Co), tungsten (W), aluminum (Al), ruthenium (Ru), iridium (Ir), molybdenum (Mo), platinum (Pt), tantalum (Ta), titanium (Ti), rhodium (Rh), or conductive metal nitrides, or any combination thereof. The dielectric layer 318 may be formed of a high-k dielectric material such as, such as hafnium oxide (HfO₂), zirconium oxide (ZrO₂), vanadium oxide (VO₂), titanium oxide (TiO₂), tin oxide (SnO₂), aluminum oxide (Al₂O₃), zinc oxide (ZnO), hafnium silicon oxide (HfSiO), zirconium silicon oxide (ZrSiO), niobium oxide (Nb₂O₅), tantalum pentoxide (Ta₂O₅), or any combination thereof.

The semiconductor structure 300 further includes bit lines BL extending in the Z direction within the trench 304 between adjacent sections S_{Lm}=1, 2, 3, . . . ) and S_{Rm}=1, 2, 3, . . . ) of the left FET module TR_{L} and the right FET module TR_{R} (e.g., between the sections S_{L1} and SRI, between the sections S_{L2} and S_{R2}, and between the sections Su and S_{R3} as shown in FIGS. 3A and 3E). The bit line BL between the sections S_{Lm} and S_{Rm}=1, 2, 3, . . . ) is in direct contact with interfaces 322 on the cross sections 306S of the semiconductor layers 306 and electrically connected to the semiconductor layers 306 via the interfaces 322 in the left FET module TR_{L} in the section S_{Lm} in all memory levels Lₙ (n=1, 2, . . . ). The bit line BL between the sections S_{Lm} and S_{Rm}=1, 2, 3, . . . ) is further in direct contact with interfaces 322 on cross sections 306S of the silicon layers 306 and electrically connected to the semiconductor layers 306 via the interfaces 322 in the right FET module TR_{R} in the section S_{Rm} in all memory levels Lₙ (n=1, 2, . . . ).

Conventionally, the bit lines BL are formed by either filling the trench 304 with doped polysilicon or other conductive material and etching away vertical isolation gaps between the bit lines BL to leave the conductive material as the finished bit line BL, or by deposition of a dielectric material in the trench 304 and etching vertical contact holes which will connect to each of the source-drain regions underneath them. In both cases, a common bit line BL for the left FET module TR_{L} and the right FET module TR_{R} is formed.

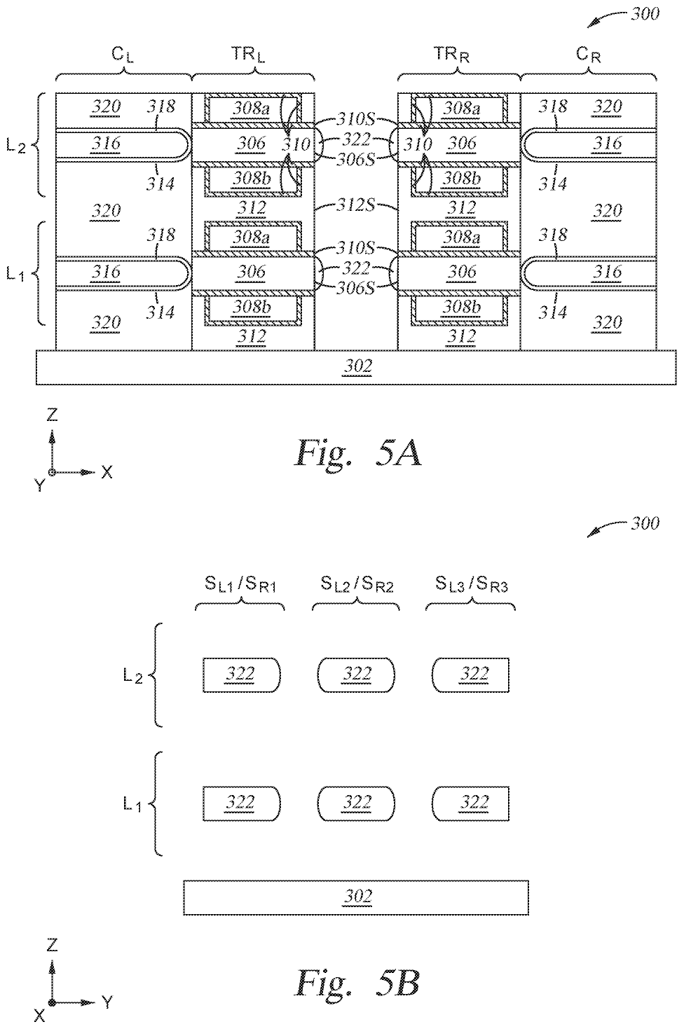

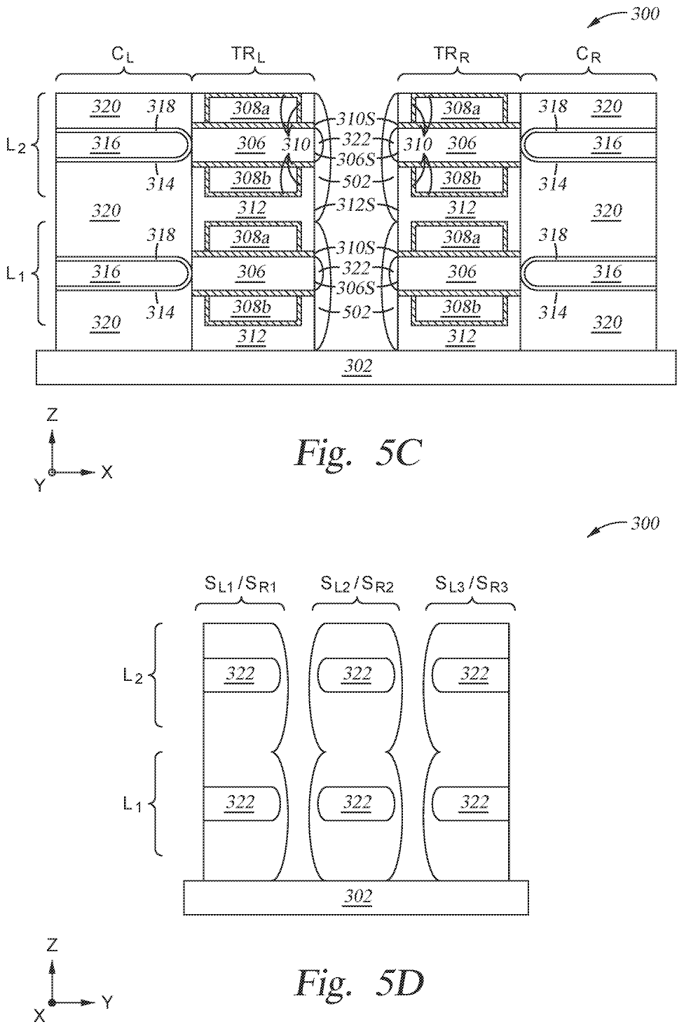

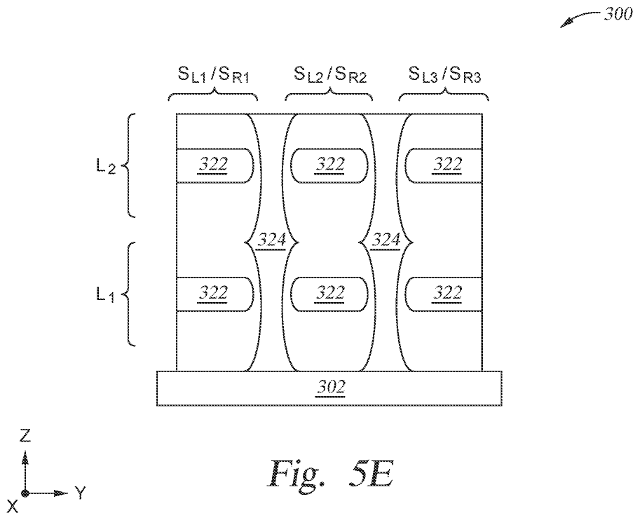

In the embodiments described herein, bit lines BL are formed using selective depositions, which can also allow two separate bit lines BL on the left FET module TR_{L} and right FET module TR_{R}. First, doped source/drain regions are formed using a suitable doping method on the exposed cross sections 306S of the semiconductor layer 306. These doped source/drain regions may or may not bridge to connect the bit line BL vertically. Subsequently, another selective deposition of metal is performed to form metal silicide interfaces 322, followed by deposition of the same, or even different metal, to form a metal interconnection layer (referenced as 502 in FIG. 5C). The metal silicide may be molybdenum silicide (MoₓSi_{y}), titanium silicide (TiₓSi_{y}), cobalt silicide (CoₓSi_{y}), nickel (NiₓSi_{y}), tantalum silicide (TaₓSi_{y}), or any combination thereof. The interfaces 322 provide an ohmic contact between the semiconductor layers 306 and the bit lines BL. The bit lines BL may be formed of metal such as molybdenum (Mo), titanium (Ti), cobalt (Co), nickel (Ni), tantalum (Ta), or any combination thereof. The selectively deposited materials may be the silicon layer, the silicide layer or the metal layer, or any combination thereof, as long as they bridge and form a continuous vertical connection to form a bit line BL. The trench 304 and bit lines BL are finally given a dielectric layer 324 to isolate bit lines BL, which may also partially or fully fill the trench 304. The trench 304 can be left with air-gaps buried below the surface to reduce the parasitic capacitance of the bit lines BL but is sealed at the top surface to allow processing of top interconnect lines for the individual vertical bit lines BL. The dielectric layer 324 is formed of dielectric material, such as silicon dioxide (SiO₂), silicon nitride (Si₃N₄), silicon oxynitride (SiON), boron-nitride (BN), silicon oxycarbide (SiOCN), boron-doped silicon oxycarbonitride (SiOCBN), aluminum oxide (Al₂O₃), or hafnium oxide (HfO₂), or any combination thereof.

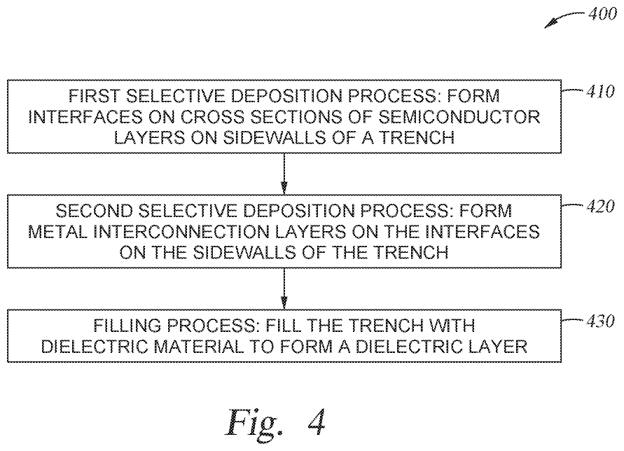

FIG. 4 depicts a process flow diagram of a method 400 of forming a bit line BL between FET modules TR_{L} and TR_{R} in the semiconductor structure 300 according to one or more implementations of the present disclosure. FIGS. 5A and 5C are cross-sectional views of a portion of the semiconductor structure 300 along the line B-B′ shown in FIG. 3A, and FIGS. 5B, 5D, and 5E are cross-sectional views of a portion of the semiconductor structure 300 along the line E-E′ shown in FIG. 3A, corresponding to various states of the method 400. It should be understood that FIGS. 5A, 5B, 5C, 5D, and 5E illustrate only partial schematic views of the semiconductor structure 300, and the semiconductor structure 300 may contain any number of transistor sections and additional materials having aspects as illustrated in the figures. It should also be noted that although the method illustrated in FIG. 4 is described sequentially, other process sequences that include one or more operations that have been omitted and/or added, and/or has been rearranged in another desirable order, fall within the scope of the embodiments of the disclosure provided herein.

The FET modules TR_{L} and TR_{R} in the semiconductor structure 300 including the semiconductor layers 306, the word line metal layers 308a, the word line metal layers 308b, the gate oxides 310, the spacer 312, the first plate metal layers 314, the second plate metal layers 316, the dielectric layers 318, the dielectric layers 320, and the dielectric layers 324 may be formed, prior to forming a bit line BL by the method 400, using any suitable deposition technique, such as chemical vapor deposition (CVD), atomic layer deposition (ALD), or physical vapor deposition (PVD), and patterning technique, such as a lithography and etch process. The semiconductor layers 306 may each have width in the Y direction of between about 20 nm and about 60 nm, for example, about 40 nm, and thickness in the Z direction of between about 10 nm and about 30 nm, for example, about 20 nm. A horizontal spacing between the adjacent semiconductor layers 306 in the Y direction may be between about 140 nm and about 180 nm, for example, about 160 nm, and a vertical spacing between the adjacent semiconductor layers 306 in the Z direction may be between about 50 nm and about 100 nm, for example, about 80 nm. The bit lines BL may have width in the Y direction of between about 40 nm and about 120 nm, for example, about 80 nm, and thickness in the X direction of between about 40 nm and about 120 nm, for example, about 80 nm.

The method 400 begins with block 410, in which a first selective deposition process is performed to form interfaces 322 self-aligned on exposed cross sections 306S of the semiconductor layers 306 on the sidewalls of the trench 304 (including the cross sections 306S of the semiconductor layers 306, cross sections 310S of the gate oxides 310, and cross sections 312S of the spacer 312), as shown in FIGS. 5A and 5B. The first selective deposition begins with a suitable doping method to form a doped source/drain region at the cross section 306S of the semiconductor layer 306. The first selective deposition continues with selective deposition of metal silicide, such as molybdenum silicide (MoₓSi_{y}), titanium silicide (TiₓSi_{y}), cobalt silicide (CoₓSi_{y}), nickel (NiₓSi_{y}), tantalum silicide (TaₓSi_{y}), or any combination thereof, to form an interface 322 at the exposed cross section 306S of the semiconductor layer 306. The interfaces 322 provides ohmic contacts between the semiconductor layers 306 and the bit line BL to be formed.

In some embodiments, the metal source may include molybdenum (Mo), titanium (Ti), cobalt (Co), nickel (Ni), tantalum (Ta), or any combination thereof. The etching gas includes an etchant gas and a carrier gas, where the etchant gas may be a by-product of the deposition gas itself. The etchant gas may include a chlorine containing gas, such as hydrogen chloride (HCl), chlorine (Cl₂), carbon tetrachloride (CCl₄), chloroform (CHCl₃), dichloromethane (CH₂Cl₂), or chloromethane (CH₃Cl). The carrier gas may include nitrogen (N₂), argon (Ar), helium (He), or hydrogen (H₂).

The deposition process may include any appropriate deposition process, such as epitaxial deposition, atomic layer deposition (ALD), chemical vapor deposition (CVD), spin-on, physical vapor deposition (PVD), or the like. The deposition process and the etch process in block 410 may be each performed in a processing chamber, such as the processing chamber 120, 122, 124, 126, 128, or 130 shown in FIG. 1, at a temperature of between about 300° C. and about 800° C. and at a pressure of between 1° Torr and 50° Torr.

In block 420, a second selective deposition process is performed to form metal interconnection layers 502 self-aligned on exposed surfaces of the interfaces 322 on the sidewalls of the trench 304 (including the interfaces 322, the cross sections 310S of the gate oxides 310, and the cross sections 312S of the spacer 312), as shown in FIGS. 5C and 5D. The second selective deposition process is a continuation of the first selective deposition process in block 410, such that there is a net deposition of material on the interfaces 322 and a zero deposition or net etching of the material on the surrounding surfaces of the sidewalls of the trench 304 (including cross sections 310S of the gate oxides 310 and cross sections 312S of the spacer 312). In the deposition process, the exposed surfaces of the trench 304 are exposed to the deposition gas containing a metal source. The metal source may be the same as the metal source used in block 410 or different from the metal source used in block 410. The interfaces 322 react with the metal source to form metal interconnection layers 502. The metal interconnection layers 502 grow from each of the interfaces 322 towards the middle of the trench 304 in the X direction and isotopically in the Y-Z plane, and merge with portions that grow from adjacent interfaces 322. The merged metal interconnection layers 502 adjacent to the FET module TR_{L} further merge with the merged metal interconnection layers 502 adjacent to the FET module TR_{R} and form a continuous bit line BL, as shown in FIGS. 3B and 3E. In some other embodiments, the merged metal interconnection layers 502 adjacent to the FET module TR_{L} alone form a bit line BL, and the merged metal interconnection layers 502 adjacent to the FET module TR_{R} form a separate bit line BL.

In some embodiments, the metal source may include molybdenum (Mo), titanium (Ti), cobalt (Co), nickel (Ni), tantalum (Ta), or any combination thereof.

In block 430, a filling process is performed to fill the trench 304 with dielectric material to form a dielectric layer 324, as shown in FIG. 5E.

The dielectric layer 324 is formed of dielectric material, such as silicon dioxide (SiO₂), silicon nitride (Si₃N₄), silicon oxynitride (SiON), boron nitride (BN), silicon oxycarbide (SiOCN), boron-doped silicon oxycarbonitride (SiOCBN), aluminum oxide (Al₂O₃), or hafnium oxide (HfO₂) or any combination thereof.

The filling process in block 430 may include any appropriate deposition process, such as a chemical vapor deposition (CVD) process, in a processing chamber, such as the processing chamber 120, 122, 124, 126, 128, or 130 shown in FIG. 1.

The embodiments described herein provide systems and methods for forming vertical bit lines in 3D DRAM devices with interfaces between the vertical bit lines and a FET device that forms a memory cell. The vertical bit lines are formed by a self-aligning deposition process, of metal such as molybdenum (Mo), without need for HAR etching process to form slots for vertical bit lines. Thus, resistance of the bit lines is reduced, as compared to polycrystalline that has been conventionally used as bit lines that may include voids. The interfaces are formed of metal silicide, such as molybdenum silicide (MoSi₂), by a selective self-aligning deposition process, and provide an ohmic contact between the FET device and the vertical bit lines, reducing contact parasitic resistance.

While the foregoing is directed to embodiments of the present disclosure, other and further embodiments of the disclosure may be devised without departing from the basic scope thereof, and the scope thereof is determined by the claims that follow.

1. A semiconductor structure, comprising:
a plurality of memory levels stacked in a first direction, each of the plurality of memory levels comprising:
a semiconductor layer;
a word line metal layer above the semiconductor layer in the first direction; and
an interface on a cross section of the semiconductor layer;
a spacer between adjacent memory levels of the plurality of memory levels in the first direction; and
a bit line in contact with the interface of each of the plurality of memory levels, the bit line extending in the first direction, wherein
the bit line comprises metal material, and
the interface comprises silicide.

2. The semiconductor structure of claim 1, wherein
the semiconductor layer comprises silicon.

3. The semiconductor structure of claim 1, wherein the metal material comprises molybdenum (Mo) and the interface comprises molybdenum silicide.

4. The semiconductor structure of claim 1, wherein the metal material comprises titanium (Ti) and the interface comprises titanium silicide.

5. The semiconductor structure of claim 1, wherein the spacer comprises silicon nitride.

6. The semiconductor structure of claim 1, wherein the semiconductor layer has:
width of between 20 nm and 60 nm in a second direction that is orthogonal to the first direction,
thickness of between 10 nm and 30 nm in the first direction, and
a vertical spacing from the semiconductor layer of an adjacent memory level of the plurality of memory levels of between 140 nm and 180 nm.

7. The semiconductor structure of claim 6, wherein the bit line has:
width of between 40 nm and 120 nm in the second direction, and
thickness of between 40 nm and 120 nm in a third direction that is orthogonal to the first direction and the second direction.

8. A method of forming a metal bit line in a semiconductor device, the method comprising:
performing a first selective deposition process to form a metal silicide layer selectively on a sidewall of a trench, the sidewall of the trench comprising a first cross section of each of a plurality of semiconductor layers stacked in a first direction, and a second cross section of a spacer disposed between adjacent semiconductor layers of the plurality of semiconductor layers;
performing a second selective deposition process to form a metal layer selectively on the sidewall of the trench; and
performing a filling process, the filling process comprising depositing dielectric material within the trench, wherein
the metal layer on the sidewall of the trench is continuous over the plurality of semiconductor layers, forming a metal bit line.

9. The method of claim 8, wherein
the semiconductor layers each comprise silicon.

10. The method of claim 8, wherein the metal layer comprises molybdenum (Mo) and the metal layer comprises molybdenum silicide.

11. The method of claim 8, wherein the metal layer comprises titanium (Ti) and the metal layer comprises titanium silicide.

12. The method of claim 9, wherein the spacer comprises silicon nitride.

13. The method of claim 8, wherein the semiconductor layers each have:
width of between 20 nm and 60 nm in a second direction that is orthogonal to the first direction,
thickness of between 10 nm and 30 nm in the first direction, and
a vertical spacing from an adjacent semiconductor layer of between 140 nm and 180 nm.

14. The method of claim 13, wherein the metal bit line has:
width of between 40 nm and 120 nm in the second direction, and
thickness of between 40 nm and 120 nm in a third direction that is orthogonal to the first direction and the second direction.

15. A three-dimensional (3D) dynamic random-access memory (DRAM) device, comprising:
a plurality of memory levels stacked in a first direction, each of the plurality of memory levels comprising:
a semiconductor layer having a first end and a second end in a second direction that is orthogonal to the first direction;
a word line metal layer; and
an interface on a cross section at the first end of the semiconductor layer;
a spacer between adjacent memory levels of the plurality of memory levels in the first direction; and
a bit line in contact with the interface of each of the plurality of memory levels, the bit line extending in the first direction, wherein
the bit line comprises metal material, and
the interface comprises silicide.

16. The 3D DRAM device of claim 15, wherein
the semiconductor layer comprises silicon.

17. The 3D DRAM device of claim 15, wherein the metal material comprises molybdenum (Mo) and the interface comprises molybdenum silicide.

18. The 3D DRAM device of claim 15, wherein the metal material comprises titanium (Ti) and the interface comprises titanium silicide.

19. The 3D DRAM device of claim 15, wherein the spacer comprises silicon nitride.

20. The 3D DRAM device of claim 15, wherein
the semiconductor layer has:
width of between 20 nm and 60 nm in the second direction,
thickness of between 10 nm and 30 nm in the first direction, and
a vertical spacing from the semiconductor layer of an adjacent memory level of the plurality of memory levels of between 140 nm and 180 nm, and
the bit line has:
width of between 40 nm and 120 nm in the second direction, and thickness of between 40 nm and 120 nm in a third direction that is orthogonal to the first direction and the second direction.
